(19) United States
(12) Patent Application Publication
(10) Pub. No.: US 2025/0085644 A1
(43) Pub. Date: Mar. 13, 2025

(54) METHODS AND APPARATUSES FOR MICROFABRICATION AND LASER WRITING ALIGNMENT

(71) Applicant: IonQ, Inc., College Park, MD (US)

(72) Inventor: Jason Madjdi AMINI, Takoma Park, MD (US)

(21) Appl. No.: 18/883,817

(22) Filed: Sep. 12, 2024

Related U.S. Application Data
(60) Provisional application No. 63/582,254, filed on Sep. 13, 2023.

(51) Int. Cl. G03F 9/00; H01L 23/544

(52) U.S. Cl. CPC G03F 9/7007; G03F 9/708; H01L 23/544; H01L 2223/54426

(57) ABSTRACT

Aspects of the present disclosure may include a method and/or a system for spatially aligning microfabrication processes and laser writing processes on a wafer by preparing a pattern of alignment features across a wafer with known relative locations and orientations between elements of the pattern, aligning one or more laser writing processes to the alignment patterns, laser writing features into the wafer based on the prior process alignment, aligning one or more microfabrication processes to the microfabrication alignment patterns, and processing the wafer via the microfabrication steps using the results of the prior alignment step.

### CROSS REFERENCE TO RELATED APPLICATION

The current application claims priority to, and the benefit of, U.S. Provisional Application No. 63/582,254 filed on Sep. 13, 2023 and entitled “METHODS AND APPARATUSES FOR MICROFABRICATION AND LASER WRITING ALIGNMENT,” the contents of which are hereby incorporated by reference in their entireties.

### TECHNICAL FIELD

The current application relates to microfabrication and laser writing processes.

### BACKGROUND

Certain devices may utilize both microfabrication processes, such as lithography based methods, and laser writing processes, such as used for selective laser etching on glass, to manufacture. The microfabrication processes and the laser writing processes typically require different tools, and sometimes, may be fabricated at different locations. Both processes generate patterns of material addition (e.g. patterned deposition of metal) or subtraction (e.g. selective etching of glass) in the fabricated devices. However, the microfabricated patterns and the laser written patterns may need to be spatially aligned on the devices so that the devices function as intended. Therefore, alignment between the microfabricated patterns and laser written patterns is desirable.

### SUMMARY

The following presents a simplified summary of one or more aspects to provide a basic understanding of such aspects. This summary is not an extensive overview of all contemplated aspects and is intended to neither identify key or critical elements of all aspects nor delineate the scope of any or all aspects. Its sole purpose is to present some concepts of one or more aspects in a simplified form as a prelude to the more detailed description that is presented later.

Aspects of the disclosure may include a wafer that might be, but not limited to, silicon or glass. That wafer being the fabrication substrate for the device fabrication with one or more devices being fabricated on a single wafer. The wafer may be prepared and/or processed according to the methods in this disclosure.

Aspects of the present disclosure may include a method for spatially aligning the microfabrication processes and laser writing processes by preparing a pattern of alignment features across a wafer with known relative locations and orientations between elements of the pattern, aligning one or more laser writing processes to one or more of the alignment patterns, processing the wafer via one or more laser writing steps using the results of the prior alignment step, aligning one or more microfabrication process steps to one or more of the alignment patterns, and processing the wafer via the microfabrication steps using the results of the prior alignment step.

Aspects of the present disclosure may include laser writing one or more alignment marks to the wafer after the aforementioned alignment of the laser writing process or processes to the alignment marks so as to allow for measurement of the placement accuracy of the laser writing alignment to the alignment marks.

Aspects of the present disclosure may include preparing additional alignment marks after the aforementioned alignment of the microfabrication process or processes to the prior alignment marks so as to allow for measurement of the placement accuracy of the microfabrication features to the laser written features.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIGS. 1A-B illustrate an example of a process for microfabrication and laser writing alignment according to aspects of the present disclosure.

FIGS. 2A-B illustrate an example of a method for microfabrication and laser writing alignment according to aspects of the present disclosure.

### DETAILED DESCRIPTION

The detailed description set forth below in connection with the appended drawings is intended as a description of various configurations and is not intended to represent the only configurations in which the concepts described herein may be practiced. The detailed description includes specific details for the purpose of providing a thorough understanding of various concepts. However, it will be apparent to those skilled in the art that these concepts may be practiced without these specific details. In some instances, well known components are shown in block diagram form in order to avoid obscuring such concepts.

In an aspect of the present disclosure, some devices used in a QIP system may include components fabricated on a single wafer (e.g., glass or silicon) using both microfabrication processes and laser writing processes. Since there may be electrical and/or optical interactions between the microelectronic devices and the laser written regions, alignment throughout the microfabrication processes and the laser writing processes are important for proper function of the QIP system. However, the microfabrication processes and the laser writing processes might not be integrated (i.e., processed at two or more separate sites). Therefore, alignment may be difficult to achieve.

A particular case for such a device is an ion trap fabricated from a glass wafer using microfabrication to provide electrical features and laser writing to prepare the substrate for shaping.

The process of laser writing glass wafers for shaping may be different from the microfabrication process used to build the electrical features on the wafer. However, both processes have to align to each other at the few micron scale. An aspect of the present disclosure includes an intra-process alignment method that (a) provides references for the laser writing with respect to the microfabrication and (b) provides confirmation of the alignment accuracy prior to full fabrication. Specifically, the microfabrication process is used to define the alignment patterns that both the microfabrication process and the laser writing process are aligned to. As such, proper alignment between the microfabrication process and the laser writing process may be achieved.

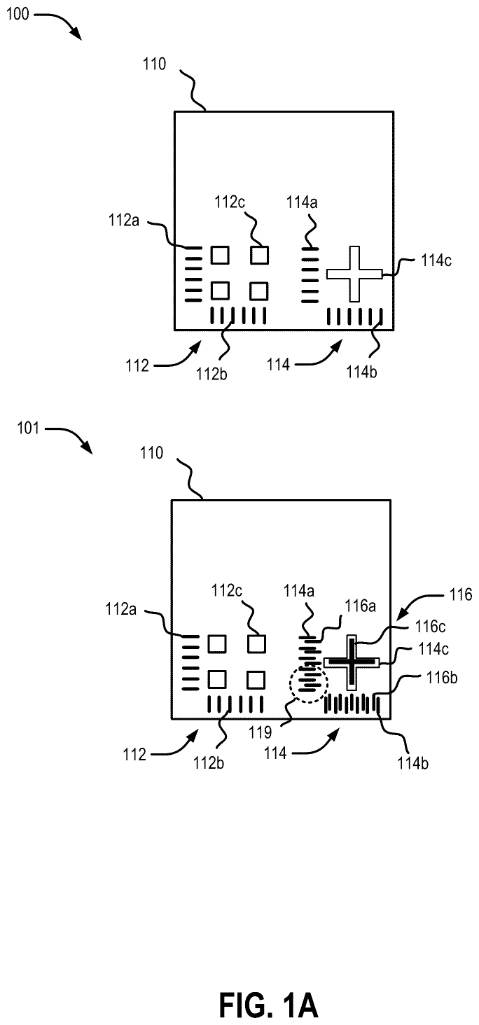

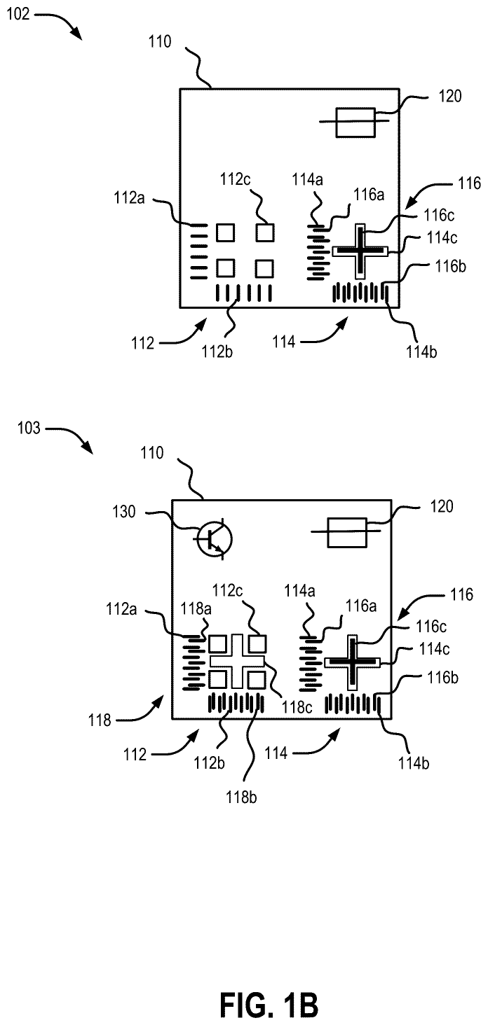

FIGS. 1A-B illustrate an example of process flow for generating alignment marks for the microfabrication process and the laser writing process. At step 100, microfabrication alignment patterns 112 and laser-to-microfabrication alignment patterns 114 may be deposited onto a wafer 110. The microfabrication alignment patterns 112 and/or the laser-to-microfabrication alignment patterns 114 may be deposited using one or more of the following methods: sputtering, evaporation, photolithography, wet etching, reactive ion etching, etc. The microfabrication alignment patterns 112 may include one or more vertical vernier marks 112a, horizontal vernier marks 112b, and/or alignment marks 112c. The laser-to-microfabrication alignment patterns 114 may include one or more vertical vernier marks 114a, horizontal vernier marks 114b, and/or alignment marks 114c. Other patterns and/or designs may also be used for the microfabrication alignment patterns 112 and/or the laser-to-microfabrication alignment patterns 114. Multiple copies of these patterns, mixes of different patterns, or both may be distributed across the wafer.

The distance and orientation between the microfabrication alignment patterns 112 and the laser-to-microfabrication alignment patterns 114 are predefined, for example in the mask by a layout engineer.

At step 101, the laser writing process references the alignment features, including the laser-to-microfabrication alignment patterns 114, to calibrate the laser writing pattern to the wafer position and orientation. As part of the laser writing pattern, the laser writing process writes laser-written alignment patterns 116 adjacent (for example) to the laser-to-microfabrication alignment patterns 114.

In some implementations, the laser-written alignment patterns 116 may include one or more vertical vernier marks 116a, horizontal vernier marks 116b, and/or alignment marks 116c. The one or more vertical vernier marks 116a, horizontal vernier marks 116b, and/or alignment marks 116c may be aligned to the one or more vertical vernier marks 114a, horizontal vernier marks 114b, and/or alignment marks 114c. The vertical vernier marks 114a, 116a may be used to estimate any vertical misalignment between the laser-to-microfabrication alignment patterns 114 and the laser-written alignment patterns 116. The horizontal vernier marks 114b, 116b may be used to estimate any horizontal misalignment between the laser-to-microfabrication alignment patterns 114 and the laser-written alignment patterns 116.

In the example shown in FIG. 1A, the center finger of the horizontal vernier marks 116b is aligned to the center gap of the horizontal vernier marks 114b. Therefore, there is no discernable horizontal misalignment between the laser-to-microfabrication alignment patterns 114 and the laser-written alignment patterns 116. However, the bottom finger of the vertical vernier marks 116a is aligned to the bottom gap of the vertical vernier marks 114a. Therefore, there is a vertical misalignment 119 between the laser-to-microfabrication alignment patterns 114 and the laser-written alignment patterns 116.

Referring to FIGS. 1A-B, at step 102, one or more laser written devices 120 may be written or fabricated on the wafer 110. In some implementations, the one or more laser written devices 120 may include optical and/or electrical devices that are fabricated using laser etching. Examples of the one or more laser written devices 120 may include waveguides, reflectors, beam splitters, etc. In other implementations, the one or more laser written devices 120 may include laser writing in the glass that prepares the wafer for selective etching at laser stages of fabrication. Other optical and/or electrical devices may also be fabricated on the wafer 110.

In some implementations, the one or more laser written devices may be fabricated before, during, or after the marking of the laser-written alignment patterns 116.

At step 103, the microfabrication processes align to the microfabrication alignment patterns 112 and one or more microfabrication devices 130 may be fabricated onto the wafer 110. Examples of the one or more microfabrication devices 130 may include transistors, diodes, vias, interconnects, passivation layers, etc. Other electrical and/or optical devices may also be fabricated on the wafer 110.

As part of the microfabrication process, additional microfabrication-to-laser alignment patterns 118 may be marked onto or near the microfabrication alignment patterns 112. For example, the microfabrication-to-laser alignment patterns 118 may be marked by etching a portion of the microfabrication alignment patterns 112. In another example, the microfabrication-to-laser alignment patterns 118 may be marked by depositing and patterning processes using conventional methods.

In some implementations, the microfabrication-to-laser alignment patterns 118 may include one or more vertical vernier marks 118a, horizontal vernier marks 118b, and/or alignment marks 118c. The one or more vertical vernier marks 118a, horizontal vernier marks 118b, and/or alignment marks 118c may be aligned to the one or more vertical vernier marks 112a, horizontal vernier marks 112b, and/or alignment marks 112c. The vertical vernier marks 112a, 118a may be used to estimate any vertical misalignment between the microfabrication alignment patterns 112 and the microfabrication-to-laser alignment patterns 118. The horizontal vernier marks 112b, 118b may be used to estimate any horizontal misalignment between the microfabrication alignment patterns 112 and the microfabrication-to-laser alignment patterns 118.

In some implementations, there may be no discernable misalignment between the microfabrication alignment patterns 112 and the microfabrication-to-laser alignment patterns 118.

In some implementations, microfabrication-to-laser alignment patterns 118 might be marked near the laser-to-microfabrication alignment patterns 114 instead of the microfabrication alignment patterns 112 with estimates of any misalignment made between microfabrication-to-laser alignment patterns 118 and laser-to-microfabrication alignment patterns 114 instead.

In some aspects, any misalignment between the one or more laser written devices 120 and the one or more microfabrication devices 130 may be determined based on the microfabrication alignment patterns 112, the laser-to-microfabrication alignment patterns 114, the laser-written alignment patterns 116, and the microfabrication-to-laser alignment patterns 118. Specifically, in the example shown in FIGS. 1A-B, there is a vertical misalignment between the laser-to-microfabrication alignment patterns 114 and the laser-written alignment patterns 116, and no misalignment between the microfabrication alignment patterns 112 and the microfabrication-to-laser alignment patterns 118. Therefore, there is a vertical misalignment between the one or more laser written devices 120 and the one or more microfabrication devices 130. The vertical misalignment may be determined based on the vertical misalignment between the laser-to-microfabrication alignment patterns 114 and the laser-written alignment patterns 116.

In some aspects, the scheme described above may be used to determine linear misalignment and/or angular misalignment. For example, the alignment patterns may be deposited at different regions of a wafer to determine angular misalignment according to aspects of the present disclosure.

The following example illustrates an example of aspects of the present disclosure. The steps in the example may include the following: (1) the microfabrication vendor may pattern the alignment layer (e.g. metal) onto the surface of the wafer where the alignment layer provides microfabrication alignment marks and alignment marks for the subsequent laser writing with the two sets having a stable and known alignment to each other (e.g. create via a single contact mask exposure); (2) the laser writing vendor may reference the laser writing process to the laser-to-microfabrication alignment marks; (3) the laser writing vendor may write the features into glass including features (“auxiliary alignment marks”) in or near the laser writing alignment marks to subsequently gauge quality of alignment; (4) optionally, the laser writing vendor may protect the alignment marks and etch the glass to form features via selective etching of the written regions; (5) optionally, the laser writing vendor may repeat (3) and (4) to build up the desired etched and written regions; (6) the laser writing vendor or microfabrication vendor may measure the position of the auxiliary alignment marks relative to the laser writing alignment marks to gauge the accuracy of the laser writing alignment; and (7) the microfabrication vendor may build the microfabrication layers aligned to the microfabrication alignment marks put down in (1).

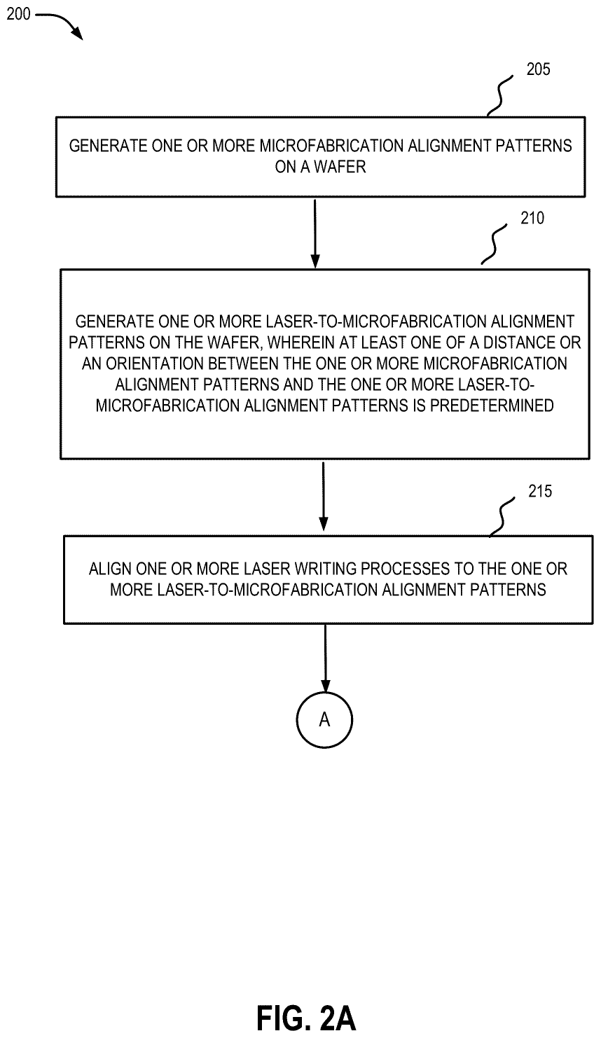

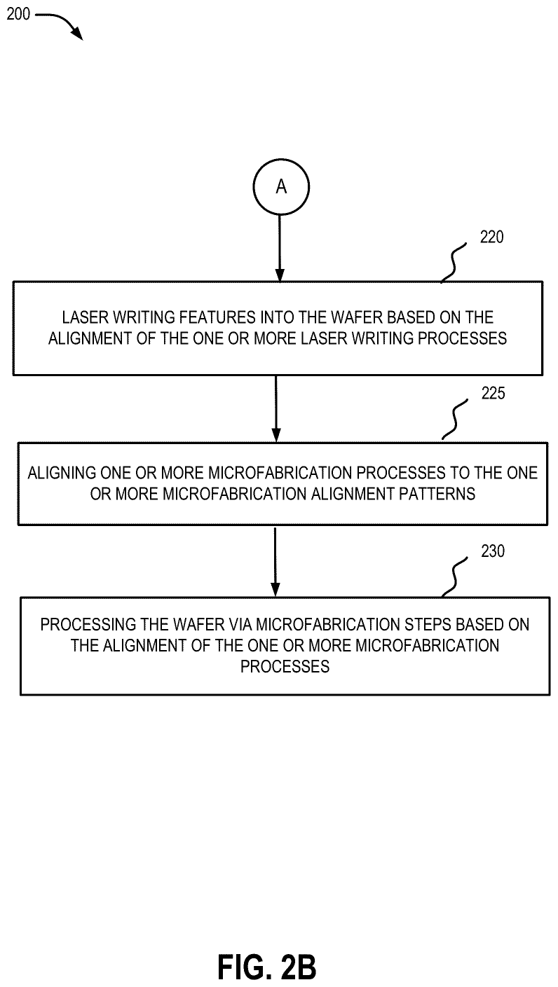

FIGS. 2A-B illustrate an example of a method 200 for microfabrication and laser writing alignment. Equipment used in a clean room known to one skilled in the art may be used to perform the method 200. Examples of the equipment include a sputterer, an evaporator, a chemical vapor deposition system, a physical vapor deposition system, a reactive ion etcher, an etching tank, a mask aligner, a microscope, a stepper, a laser, etc. Other tools may also be used to perform various aspects of the present disclosure.

At 205, the method 200 may generate one or more microfabrication alignment patterns on a wafer. For example, one or more of a sputter, an evaporator, a mask aligner, and/or a reactive ion etcher may generate one or more microfabrication alignment patterns on a wafer.

At 210, the method 200 may generate one or more laser-to-microfabrication alignment patterns on the wafer, wherein at least one of a distance or an orientation between the one or more microfabrication alignment patterns and the one or more laser-to-microfabrication alignment patterns is predetermined. For example, one or more of a sputter, an evaporator, a mask aligner, and/or a reactive ion etcher may generate one or more laser-to-microfabrication alignment patterns on the wafer, wherein at least one of a distance or an orientation between the one or more microfabrication alignment patterns and the one or more laser-to-microfabrication alignment patterns is predetermined.

At 215, the method 200 may align one or more laser writing processes to the one or more laser-to-microfabrication alignment patterns. A microscope and/or a camera may be used to align the one or more laser writing processes to the one or more laser-to- microfabrication alignment patterns. The laser writing process may then write the laser-to-microfabrication alignment patterns for measurement of alignment accuracy.

At 220, the method 200 may laser write features into the wafer based on the alignment of the one or more laser writing processes. For example, one or more of a laser and/or other laser writing tools known to one skilled in the art may prepare via laser writing one or more devices based on the alignment of the laser writing process to the laser writing alignment patterns.

At 225, the method 200 may align one or more microfabrication processes to the one or more microfabrication alignment patterns. For example, one or more of a sputter, an evaporator, a mask aligner, and/or a reactive ion etcher may align one or more microfabrication processes to the one or more microfabrication alignment patterns.

At 230, the method 200 may process the wafer via microfabrication steps based on the alignment of the one or more microfabrication processes. For example, one or more of a sputter, an evaporator, a mask aligner, a reactive ion etcher, a physical vapor deposition system, a chemical vapor deposition system, and/or other microfabrication tools known to one skilled in the art may the wafer via microfabrication steps based on the alignment of the one or more microfabrication processes.

Aspects of the present disclosure may include a method and/or a system for generating one or more microfabrication alignment patterns on a wafer, generating one or more laser-to-microfabrication writing alignment patterns on the wafer, wherein at least one of a distance or an orientation between the one or more microfabrication alignment patterns and the one or more laser-to-microfabrication alignment patterns is predetermined, aligning one or more laser writing processes to the laser-to-microfabrication alignment patterns, laser writing features into the wafer based on the prior process alignment, aligning one or more microfabrication processes to the microfabrication alignment patterns, and processing the wafer via the microfabrication steps using the results of the prior alignment step.

Aspects of the present disclosure include any of the methods and/or systems above, wherein aligning the one or more laser-written alignment patterns comprises etching the one or more laser-written alignment patterns onto at least a portion of the one or more laser writing alignment patterns.

Aspects of the present disclosure include any of the methods and/or systems above, further comprising determining at least one of a vertical linear alignment, a horizontal linear alignment, or an angular misalignment between the one or more microfabrication-to-laser alignment patterns and the one or more microfabrication alignment patterns.

Aspects of the present disclosure include any of the methods and/or systems above, wherein the one or more microfabrication alignment patterns includes first vernier marks, the one or more microfabrication-to-laser alignment patterns includes second vernier marks, and determining the at least one of the vertical linear alignment, the horizontal linear alignment, or the angular misalignment comprises determining based on the first vernier marks and the second vernier marks.

Aspects of the present disclosure include any of the methods and/or systems above, further comprising determining at least one of a vertical linear alignment, a horizontal linear alignment, or an angular misalignment between the one or more laser-written alignment patterns and the one or more laser-to-microfabrication alignment patterns.

Aspects of the present disclosure include any of the methods and/or systems above, wherein the one or more laser-to-microfabrication alignment patterns includes first vernier marks, the one or more laser-written alignment patterns includes second vernier marks, and determining the at least one of the vertical linear alignment, the horizontal linear alignment, or the angular misalignment comprises determining based on the first vernier marks and the second vernier marks.

Aspects of the present disclosure include any of the methods and/or systems above, further comprising determining at least one of a total vertical linear alignment, a total horizontal linear alignment, or a total angular misalignment between the one or more laser writing devices and the one or more microfabrication devices based on a first misalignment between the one or more microfabrication-to-laser alignment patterns and the one or more microfabrication alignment patterns and a second misalignment between the one or more laser-written alignment patterns and the one or more laser-to-microfabrication alignment patterns.

Aspects of the present disclosure include any of the methods and/or systems above, wherein the wafer is a glass wafer or a silicon wafer.

Aspects of the present disclosure include any of the methods and/or systems above, wherein generating the one or more microfabrication alignment patterns and generating the one or more laser-to-microfabrication alignment patterns comprises using a single mask.

Aspects of the present disclosure include any of the methods and/or systems above. The previous description of the disclosure is provided to enable a person skilled in the art to make or use the disclosure. Various modifications to the disclosure will be readily apparent to those skilled in the art, and the common principles defined herein may be applied to other variations without departing from the spirit or scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

What is claimed is:

1. A method of alignment, comprising:
generating one or more microfabrication alignment patterns on a wafer;
generating one or more laser-to-microfabrication alignment patterns on the wafer, wherein at least one of a distance or an orientation between the one or more microfabrication alignment patterns and the one or more laser-to-microfabrication alignment patterns is predetermined;
aligning one or more laser writing processes to the one or more laser-to-microfabrication alignment patterns;
laser writing features into the wafer based on the alignment of the one or more laser writing processes;
aligning one or more microfabrication processes to the one or more microfabrication alignment patterns; and
processing the wafer via microfabrication steps based on the alignment of the one or more microfabrication processes.

2. The method of claim 1, wherein the laser writing includes generating one or more laser-written alignment marks for assessing an alignment of the one or more laser writing processes to one or more laser-to-microfabrication alignment marks of the laser-to-microfabrication alignment patterns.

3. The method of claim 2, wherein the processing of the wafer via the microfabrication steps includes generating one or more microfabrication-to-laser alignment marks for assessing an alignment of the one or more microfabrication processes to the one or more microfabrication alignment marks, one or more laser-to-microfabrication alignment marks, one or more laser-written alignment marks, or a combination thereof.

4. The method of claim 2, further comprising determining at least one of a vertical linear misalignment, a horizontal linear misalignment, or an angular misalignment between the one or more laser-written alignment marks and the one or more laser-to-microfabrication alignment marks.

5. The method of claim 3, further comprising determining at least one of a vertical linear misalignment, a horizontal linear misalignment, or an angular misalignment between the microfabrication-to-laser alignment marks and the one or more laser-written alignment marks.

6. The method of claim 2, wherein:
the one or more laser-to-microfabrication alignment marks includes first vernier marks;
the one or more laser-written alignment marks includes second vernier marks; and
further comprising determining at least one of a vertical linear misalignment, a horizontal linear misalignment, or an angular misalignment between the one or more laser-written alignment marks and the one or more laser-to-microfabrication alignment marks based on the first vernier marks and the second vernier marks.

7. The method of claim 3, wherein:
the one or more laser-written alignment marks includes first vernier marks;
the one or more microfabrication-to-laser alignment marks includes second vernier marks; and
further comprising determining at least one of a vertical linear misalignment, a horizontal linear misalignment, or an angular misalignment between the one or more microfabrication alignment marks and the laser-written alignment marks based on the first vernier marks and the second vernier marks.

8. The method of claim 1, wherein the wafer is a glass wafer or a silicon wafer.

9. The method of claim 1, wherein generating the one or more microfabrication alignment patterns and generating the one or more laser-to-microfabrication alignment patterns comprises generating the one or more microfabrication alignment patterns and the one or more laser-to-microfabrication alignment patterns using a single mask.

10. A wafer, comprising:
one or more microfabrication alignment patterns;
one or more laser-to-microfabrication alignment patterns, wherein at least one of a distance or an orientation between the one or more microfabrication alignment patterns and the one or more laser-to-microfabrication alignment patterns is predetermined;
first features generated by one or more laser writing processes aligned to the one or more laser-to-microfabrication alignment patterns; and
second features generated by one or more microfabrication processes aligned to the one or more microfabrication alignment patterns.

11. The wafer of claim 10 further comprises one or more laser-written alignment marks generated by the one or more laser writing process for assessing a first alignment of the one or more laser writing processes to one or more laser-to-microfabrication alignment marks of the one or more laser-to-microfabrication alignment patterns.

12. The wafer of claim 11, further comprises one or more microfabrication-to-laser alignment marks generated by the one or more microfabrication processes for assessing a second alignment of the microfabrication processes to the one or more laser-written alignment marks associated with the one or more laser writing processes to one or more microfabrication alignment marks, one or more laser-to-microfabrication alignment marks, or a combination thereof.

13. The wafer of claim 12, wherein:
the one or more laser-to-microfabrication alignment marks includes first vernier marks; and
the one or more laser-written alignment marks includes second vernier marks.

14. The wafer of claim 12, wherein:
the one or more laser-written alignment marks includes first vernier marks; and
the one or more microfabrication-to-laser alignment marks includes second vernier marks.

15. The wafer of claim 10, wherein the wafer is a glass wafer or a silicon wafer.

16. The wafer of claim 10, wherein the one or more microfabrication alignment patterns and the one or more laser-to-microfabrication alignment patterns are generated using a single mask.
